(19) United States
(12) Patent Application Publication
(10) Pub. No.: US 2007/0238284 A1
(43) Pub. Date: Oct. 11, 2007

(54) Touch panel fabrication method

(75) Inventors: Chun-Hao Wang, Changhua County (TW); Chin-Pei Hwang, Taichung City (TW); Wen-Tsung Wang, Taichung County (TW); Sung-Hao Chu, Taichung City (TW)

Correspondence Address: BACON & THOMAS, PLLC, 625 SLATERS LANE, FOURTH FLOOR, ALEXANDRIA, VA, 22314, US

(73) Assignee: Wintek Corporation, Taichung (TW)

(21) Appl. No.: 11/392,590

(22) Filed: Mar. 30, 2006

(51) Int. Cl. H01L 21/4763

(52) U.S. Cl. 438/618

(57) ABSTRACT

A touch panel fabrication method includes the steps of (a) preparing a first substrate and a second substrate, (b) disposing a seal frame having an opening on the first substrate, (c) coupling the first substrate and the second substrate together by the seal frame such that a vacancy is defined by the first substrate, the second substrate and the seal frame, and (d) filling up the vacancy with a dielectric material through the opening of the seal frame.

### BACKGROUND OF THE INVENTION

1. Field of the Invention

The present invention relates to touch panels for electronic products and more particularly, to the fabrication method of a touch panel.

2. Description of the Related Art

Nowadays, more and more electronic products use a touch panel as the operating interface. For example, a touch panel can be directly assembled to the display screen of a PDA, Tablet PC, ATM, or any of a variety of display screen-equipped electronic products so that the user can operate the electronic product by touching the touch panel.

A touch panel for use on a display screen generally comprises two transparent substrates respectively made of hard glass and soft plastics. Each substrate has electrodes arranged on one side. The two substrates are bonded together by means of a transparent optical adhesive film. In order to quit the production of bubbles during bonding of the two substrates, the soft substrate is curved and adhered to the hard substrate gradually. This bonding method avoids the production of bubbles between the two substrates, maintaining the flatness and good outer appearance of the product.

However, when both substrates must be made of glass, which means that the substrates cannot be curved, the aforesaid bonding procedure cannot be carried out. In this case, bubbles may exist between the substrates, affecting the optical characteristics and the quality of the outer appearance of the touch panel.

### SUMMARY OF THE INVENTION

The present invention has been accomplished under the circumstances in view. It is the main object of the present invention to provide a touch panel fabrication method, which is practical for making a touch panel formed with two glass substrates, maintaining the optical characteristics and quality of outer appearance of the touch panel.

To achieve this object of the present invention, the touch panel fabrication method comprises the steps of (a) preparing a first substrate having a conducting layer and a second substrate having a conducting layer, (b) disposing a seal frame having an opening on the first substrate, (c) coupling the first substrate and the second substrate together by the seal frame such that a vacancy is defined by the first substrate, the second substrate and the seal frame, and (d) filling up the vacancy with a predetermined amount of a dielectric material through the opening of the seal frame.

### BRIEF DESCRIPTION OF THE DRAWINGS

FIG. 1 is a schematic drawing showing the first fabrication step of the touch panel fabrication method according to a first embodiment of the present invention.

FIG. 2 is a schematic drawing showing the second fabrication step of the touch panel fabrication method according to the first embodiment of present invention.

FIG. 3 is a schematic drawing showing the second substrate bonded on the first substrate according to the first embodiment of the present invention.

FIG. 4 is a sectional view taken along line 4-4 of FIG. 3.

FIG. 5 corresponds to FIG. 4, showing a dielectric material filled up the vacancy.

FIG. 6 is a sectional view of a touch panel made according to a second embodiment of the present invention.

FIG. 7 is a sectional view of a touch panel made according to a third embodiment of the present invention.

FIG. 8 is a sectional view of a touch panel made according to a fourth embodiment of the present invention.

### DETAILED DESCRIPTION OF THE INVENTION

A touch panel fabrication method in accordance with a first embodiment of the present invention comprises the following steps.

Step I: Preparing a first substrate and a second substrate

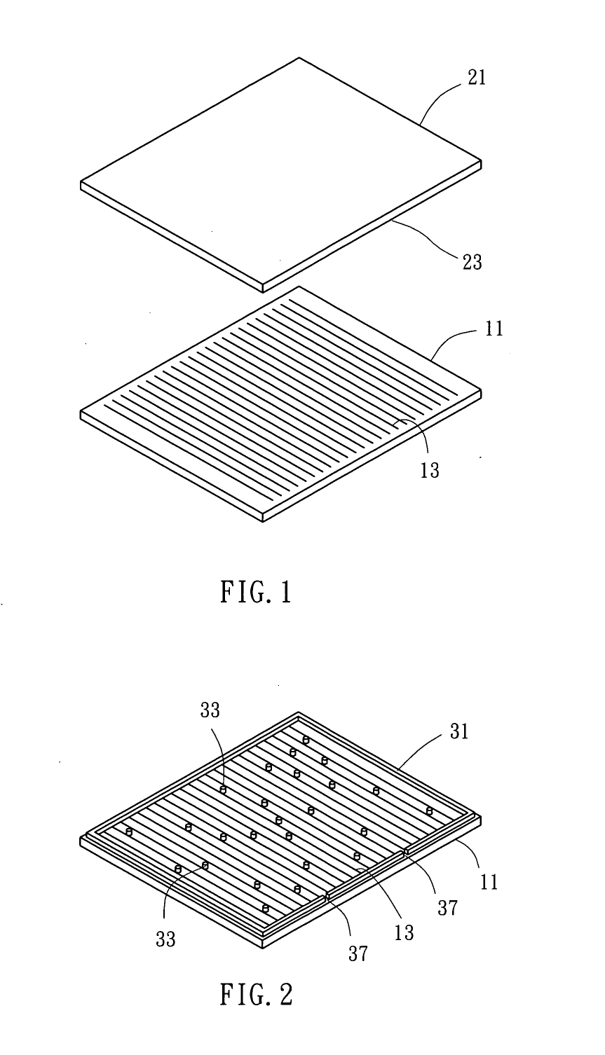

As shown in FIG. 1, a first substrate 11 and a second substrate 21 both made of glass are provided. The first substrate 11 has a side, namely a top side, on which a first conducting layer 13 is formed. The second substrate 21 has a side, namely a bottom side, on which a second conducting layer 23 is formed. According to this embodiment, the first and second conducting layers 13 and 23 are formed by depositing an ITO (Indium Tin Oxide) layer on one side of each of the first substrate 11 and the second substrate 21, and then patterning the ITO layers by the photolithography and etching processes. Since this formation method is well known in the art, no detailed description thereof is needed hereinafter.

Step II: Disposing a seal frame and spacers on the first substrate

As shown in FIG. 2, a seal frame 31 made of polymer material and a plurality of spacers 33 are applied on the top side of the first substrate 11. The seal frame 31 is substantially a rectangular frame disposing along the border of the top side of the first substrate 11 and having two openings 37 at a lateral side thereof. The spacers 33 are dispersed within the area surrounded by the seal frame 31. The spacers 33 each have a height substantially equal to that of the seal frame 31 such that the topmost edge of each spacer 33 will be kept in flush with the seal frame 31.

Step III: Coupling the first and second substrates together

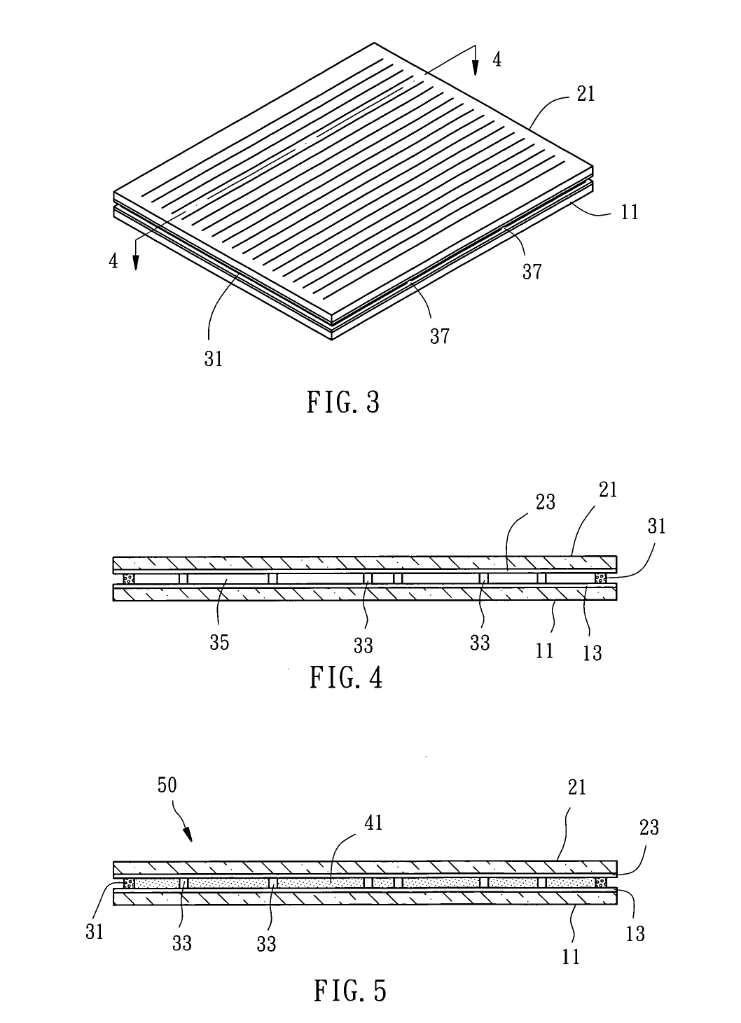

Referring to FIGS. 3 and 4, the second substrate 21 is firmly coupled to the first substrate 11 by the adhesion of the seal frame 31. In the coupling step, the second substrate 21 is first placed in alignment with the first substrate 11 and then attached with pressure to the seal frame 31. And then, a curing process is carried out so as to couple the first substrate 11 and the second substrate 21 together by means of the seal frame 31 of polymer material. As shown in FIGS. 3 and 4, the first conducting layer 13 of the first substrate 11 faces the second conducting layer 23 of the second substrate 21, and a vacancy 35 is defined by the first and second substrates 11 and 21 and the seal frame 31. It can be seen that the spacers 33 are stopped between the first substrate 11 and the second substrate 21 to control the gap between the two substrates 11 and 21.

Step IV: Preparing a dielectric material as a filling

A predetermined amount of dielectric material 41, for example, acrylic-based photosensitive resin, that has a viscosity below SOOcps is then prepare as a filling.

Step V: Filing up the vacancy

The first substrate 11 and second substrate 21, which are combined in the above-mentioned step III, are placed in a vacuum chamber (not shown), and then the pressure of the vacuum chamber is lowered by operating a vacuum pump to pump air out of the vacuum chamber to a level of about 10⁻³ torr. At the same time, the dielectric material 41 prepared in the above-mentioned step IV is applied in contact with the openings 37 of the seal frame 31. And then, the pressure of the vacuum chamber and the vacancy 35 is gradually increased to the atmospheric pressure for enabling the dielectric material 41 to be sucked into the vacancy 35 through the openings 37 to fill up the vacancy 35 as shown in FIG. 5.

Step VI: Curing the dielectric material

The openings 37 of the seal frame 31 are sealed and then a curing process is carried out to make the dielectric material 41 in the vacancy well cured, thereby forming the desired touch panel 50.

Referring to FIG. 5 again, a touch panel 50 made in accordance with the above-mentioned steps of the present invention comprises a first substrate 11, a second substrate 21, a peripheral seal frame 31, and a dielectric material 41. The first substrate 11 and the second substrate 21 are glass substrates, and the first substrate 11 is provided at the top side thereof with a first conducting layer 13 facing a second conducting layer 23 provided at the bottom side of the second substrate 21. The seal frame 31 is connected between the first substrate 11 and the second substrate 21 around the first and second conducting layers 13 and 23. Spacers 33 are sandwiched between the first substrate 11 and the second substrate 21 and located within the area surrounded by the seal frame 31 for supporting the first and second substrates 11 and 21 with a predetermined interval, i.e. the height of the spacers 33. The dielectric material 41 fills up the vacancy 35 defined by the seal frame 31 and the first and second conducting substrates 11 and 21, allowing the electric sensitivity between the conducting layers 13 and 33 and the dielectric material 41.

Because the dielectric material 41 is filled into the vacancy 35 by the process of vacuum suction, no bubbles exit between the first substrate 11 and the second substrate 21 after the vacancy 35 has been filled up with the dielectric material 41. When the user touch the second substrate 21 after connection of power supply to the touch panel 50, the user's operating condition will be sensed by detecting the capacitive effect or the inductive effect.

Therefore, a touch panel made according to the aforesaid fabrication method has optimum optical characteristics and a good outer appearance quality.

Further, the aforesaid fabrication method is not limited to the fabrication of a transparent touch panel. This fabrication method is also practical for the production of an opaque touch panel. Further, epoxy-based resin or silicon-based resin may be used to substitute for the acrylic-based resin of the dielectric material, achieving the same effect.

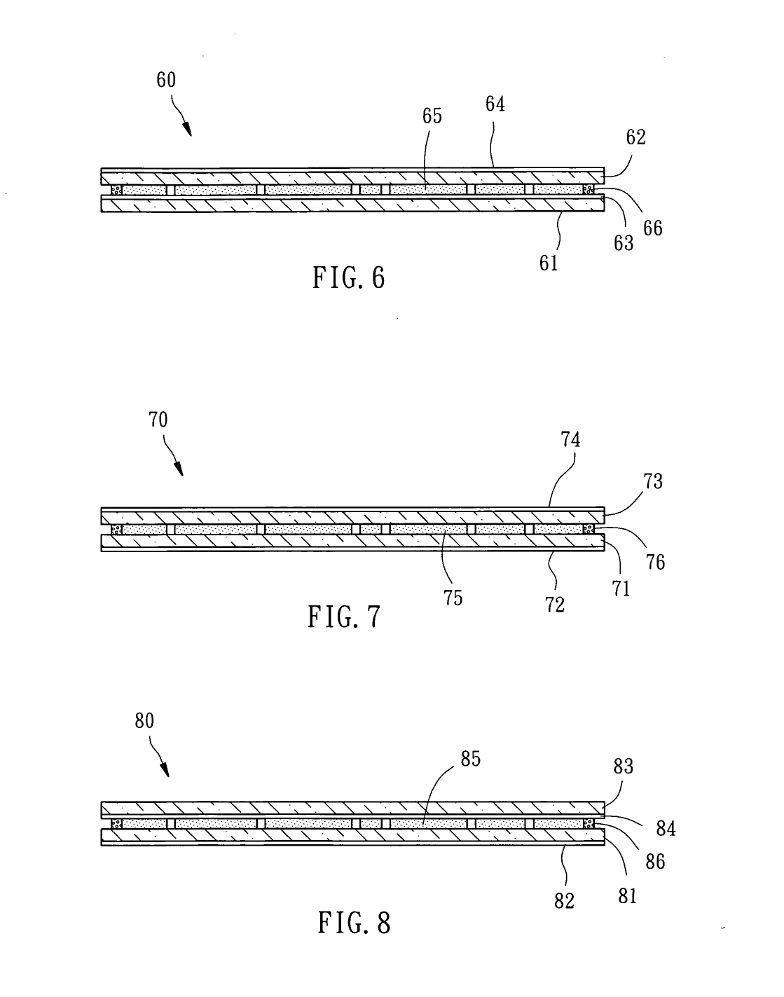

In the aforesaid embodiment, the dielectric material 41 is in contact with both of the first conducting layer 13 of the first substrate 11 and the second conducting layer 23 of the second substrate 21. Other alternate forms may be used as a substitute, enabling an electric induction to be produced between the conducting layers and the dielectric material. For example, FIG. 6 shows a touch panel constructed according to the second embodiment of the present invention. This embodiment is substantially similar to the aforesaid first embodiment of the present invention with the exception that the first conducting layer 63 and the second conducting layer 64 are respectively provided at the top side of the first substrate 61 and the top side of the second substrate 62. In other words, the first conducting layer 63 and the second conducting layer 64 face a same direction, namely an upward direction. In addition, the dielectric material 65 filled between the first and second substrates 61 and 62 and surrounded by the seal frame 66 is only in contact with the first conducting layer 63.

FIG. 7 shows a touch panel 70 constructed according to the third embodiment of the present invention. According to this embodiment, the first conducting layer 72 is provided at the bottom side of the first substrate 71 and the second conducting layer 74 is provided at the top side of the second substrate 73. In other words, the first conducting layer 72 and the second conducting layer 74 face reversed directions respectively, that is, the first conducting layer 72 faces a downward direction and the second conducting layer 74 faces an upward direction. In addition, the dielectric material 75 filled between the first substrate 71 and the second substrate 73 and surrounded by the seal frame 76 doesn't contact either the first conducting layer 72 or the second conducting layer 74.

FIG. 8 shows a touch panel 80 constructed according to the fourth embodiment of the present invention. According to this embodiment, the first conducting layer 82 is provided at the bottom side of the first substrate 81 and the second conducting layer 84 is provided at the bottom side of the second substrate 83 too. In other words, the first conducting layer 82 and the second conducting layer 84 face a same direction, namely a downward direction. In addition, the dielectric material 85 filled between the first and second substrates 81 and 83 and surrounded by the seal frame 86 is only in contact with the second conducting layer 84.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A touch panel fabrication method comprising the steps of:
(a) preparing a first substrate and a second substrate, the first substrate and the second substrate having a conducting layer respectively;
(b) disposing a seal frame on the first substrate, the seal frame having at least one opening;
(c) coupling the first substrate and the second substrate together by the seal frame such that a vacancy is defined by the first substrate, the second substrate and the seal frame; and
(d) filling up the vacancy with a predetermined amount of a dielectric material through the opening of the seal frame.

2. The touch panel fabrication method as claimed in claim 1, wherein a plurality of spacers are further disposed on the first substrate in the step (b) such that the spacers are sandwiched between the first substrate and the second substrate in the step (c).

3. The touch panel fabrication method as claimed in claim 1, wherein the dielectric material has a viscosity less than 500 cps.

4. The touch panel fabrication method as claimed in claim 1, wherein the dielectric material is filled into the vacancy by a vacuum suction process during the step (d).

5. The touch panel fabrication method as claimed in claim 1, wherein a curing process is further carried out in the step (c) such that the first substrate and the second substrate are firmly coupled with each other by the seal frame.

6. The touch panel fabrication method as claimed in claim 1, wherein a curing process is further carried out in the step (d) to cure the dielectric material.

7. The touch panel fabrication method as claimed in claim 1, wherein the conducting layer of the first substrate faces the conducting layer of the second substrate in the step (c).

8. The touch panel fabrication method as claimed in claim 1, wherein the conducting layer of the first substrate and the conducting layer of the second substrate face a same direction.

9. The touch panel fabrication method as claimed in claim 1, wherein the conducting layer of the first substrate and the conducting layer of the second substrate face respectively reversed directions.

10. The touch panel fabrication method as claimed in claim 1, wherein the first substrate and the second substrate are made of a transparent material.

11. The touch panel fabrication method as claimed in claim 1, wherein the dielectric material is a transparent material.
